(19) United States
(12) Patent Application Publication
(10) Pub. No.: US 2026/0089873 A1
(43) Pub. Date: Mar. 26, 2026

(54) SYSTEMS AND METHODS FOR THERMAL CONTROL IN AN INFORMATION HANDLING SYSTEM

(71) Applicant: Dell Products L.P., Round Rock, TX (US)

(72) Inventors: Rimple Vijay PANJWANI, Bengaluru (IN); Carlos HENRY, Georgetown, TX (US); Hasnain SHABBIR, Round Rock, TX (US); Vineet Kumar PANDEY, Sultanpur (IN); Kalpana BANGARU, Bangalore (IN)

(73) Assignee: Dell Products L.P., Round Rock, TX (US)

(21) Appl. No.: 18/892,831

(22) Filed: Sep. 23, 2024

(51) Int. Cl. H05K 7/20

(52) U.S. Cl. CPC H05K 7/20209; H05K 7/20136

(57) ABSTRACT

A method may include controlling a cooling subsystem, the cooling subsystem comprising at least one air mover configured to generate a cooling airflow in a system, based at least in part on an inlet temperature to the system when an inlet temperature sensor for sensing the inlet temperature is available and in response to a failure of the inlet temperature sensor, executing an energy balance calculation to estimate a virtual inlet temperature based on one or more temperature values from one or more temperature sensors of a plurality of temperature sensors of the system other than the inlet temperature sensor and controlling the cooling subsystem based at least in part on the virtual inlet temperature when the inlet temperature sensor is unavailable.

### TECHNICAL FIELD

The present disclosure relates in general to information handling systems, and more particularly to thermal management of an information handling system.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, thermal management systems including air movers (e.g., cooling fans and blowers) have often been used in information handling systems to cool information handling systems and their components. Various input parameters to a thermal management system, such as measurements from temperature sensors and inventories of information handling system components, are often utilized by thermal management systems to control air movers and/or throttle power consumption of components in order to provide adequate cooling of components.

One of the most critical sensors of a thermal management system is an ambient inlet temperature sensor, as it often serves as the basis for all open loop curves of the thermal management system. In traditional approaches, in the absence of the ambient inlet temperature sensor (e.g., due to temporary or permanent failure of the sensor), air movers must often run at high speeds to protect the information handling system due to heavy dependency of open loop curves on the ambient inlet temperature sensor. With information handling systems having ever increasing air mover power levels (e.g., sometimes 20%-25% of total system power), it is critical to optimize system air mover power conditions at all times, including in sensor failure conditions.

### SUMMARY

In accordance with the teachings of the present disclosure, disadvantages and problems associated with thermal management of an information handling system during a failure condition of an ambient inlet temperature sensor may be reduced or eliminated.

In accordance with embodiments of the present disclosure, a system may include a cooling subsystem comprising at least one air mover configured to generate a cooling airflow in the system, a plurality of temperature sensors including an inlet temperature sensor for sensing an inlet temperature into the system of the cooling airflow and an outlet temperature sensor for sensing an exhaust temperature from the system of the cooling airflow, and a thermal manager communicatively coupled to the cooling subsystem for control of the cooling subsystem. The thermal manager may be configured to control the cooling subsystem based at least in part on the inlet temperature when the inlet temperature sensor is available and in response to a failure of the inlet temperature sensor, execute an energy balance calculation to estimate a virtual inlet temperature based on one or more temperature values from one or more temperature sensors of the plurality of temperature sensors other than the inlet temperature sensor and control the cooling subsystem based at least in part on the virtual inlet temperature when the inlet temperature sensor is unavailable.

In accordance with these and other embodiments of the present disclosure, a method may include controlling a cooling subsystem, the cooling subsystem comprising at least one air mover configured to generate a cooling airflow in a system, based at least in part on an inlet temperature to the system when an inlet temperature sensor for sensing the inlet temperature is available and in response to a failure of the inlet temperature sensor, executing an energy balance calculation to estimate a virtual inlet temperature based on one or more temperature values from one or more temperature sensors of a plurality of temperature sensors of the system other than the inlet temperature sensor and controlling the cooling subsystem based at least in part on the virtual inlet temperature when the inlet temperature sensor is unavailable.

In accordance with these and other embodiments of the present disclosure, an article of manufacture may include a non-transitory computer-readable medium and computer-executable instructions carried on the computer-readable medium, the instructions readable by a processor, the instructions, when read and executed, for causing the processor to: control a cooling subsystem, the cooling subsystem comprising at least one air mover configured to generate a cooling airflow in a system, based at least in part on an inlet temperature to the system when an inlet temperature sensor for sensing the inlet temperature is available; and in response to a failure of the inlet temperature sensor, execute an energy balance calculation to estimate a virtual inlet temperature based on one or more temperature values from one or more temperature sensors of a plurality of temperature sensors of the system other than the inlet temperature sensor and control the cooling subsystem based at least in part on the virtual inlet temperature when the inlet temperature sensor is unavailable.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a perspective view of an example information handling system, in accordance with embodiments of the present disclosure;

FIG. 2 illustrates a mathematical model for estimating component thermal performance and setting thermal controls, in accordance with embodiments of the present disclosure;

FIG. 3 illustrates a plan view of an example information handling system, in accordance with embodiments of the present disclosure;

FIG. 4 illustrates a user interface for managing thermal conditions of a server information handling system with stored configuration settings of subsystems within the information handling system, in accordance with embodiments of the present disclosure;

FIG. 5 illustrates a user interface for estimating system airflow and inlet temperature based upon conservation of energy within an information handling system housing, in accordance with embodiments of the present disclosure; and

FIG. 6 illustrates a flow chart of an example method for estimating an inlet temperature, in accordance with embodiments of the present disclosure.

### DETAILED DESCRIPTION

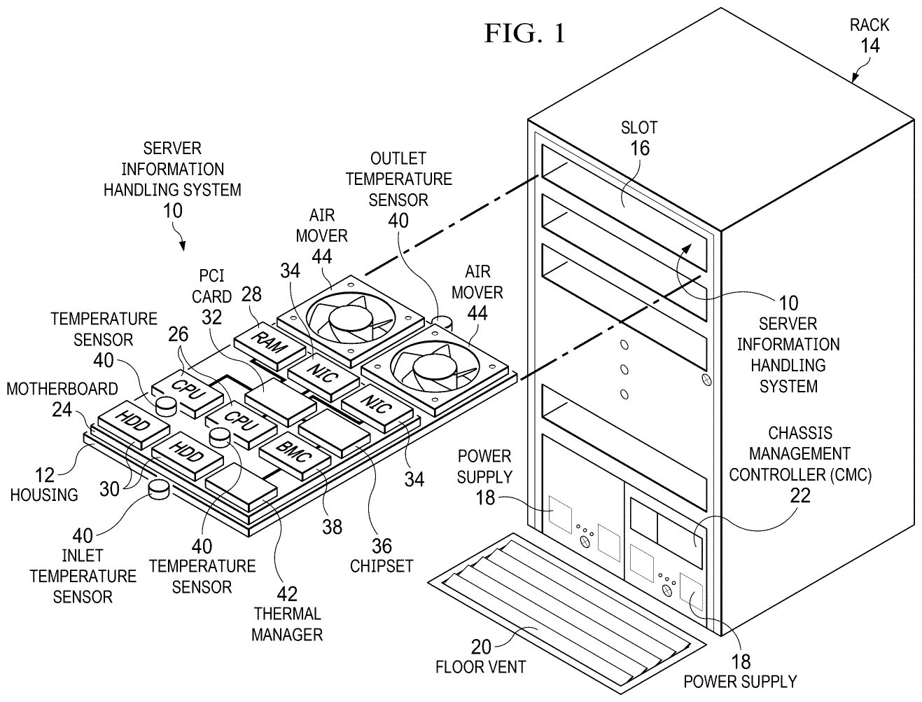

Preferred embodiments and their advantages are best understood by reference to FIGS. 1 through 6, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a perspective view of an example information handling system 10, in accordance with embodiments of the present disclosure. As shown in FIG. 1, information handling system 10 may comprise a server built into a housing 12 that resides with one or more other information handling systems 10 in a rack 14. Rack 14 may comprise a plurality of vertically-stacked slots 16 that accept information handling systems 10 and a plurality of power supplies 18 that provide electrical energy to information handling systems 10. In a data center environment, rack 14 may receive pretreated cooling air provided from a floor vent 20 to aid removal of thermal energy from information handling systems 10 disposed in rack 14. Power supplies 18 may be assigned power based upon availability at the data center and may allocate power to individual information handling systems 10 under the management of a chassis management controller (CMC) 22. CMC 22 may aid coordination of operating settings so that information handling systems 10 do not exceed thermal or power usage constraints.

Housing 12 may include a motherboard 24 that provides structural support and electrical signal communication for processing components disposed in housing 12 that cooperate to process information. For example, one or more central processing units (CPUs) 26 may execute instructions stored in random access memory (RAM) 28 to process information, such as responses to server requests by client information handling systems remote from information handling system 10. One or more persistent storage devices, such as hard disk drives (HDD) 30 may store information maintained for extended periods and during power off states. A backplane communications manager, such as a PCI card 32, may interface processing components to communicate processed information, such as communications between CPUs 26 and network interface cards (NICs) 34 that are sent through a network, such as a local area network. A chipset 36 may include various processing and firmware resources for coordinating the interactions of processing components, such as a basic input/output system (BIOS). A baseboard management controller (BMC) 38 may interface with chipset 36 to provide out-of-band management functions, such as remote power up, remote power down, firmware updates, and power management. For example, BMC 38 may receive an allocation of power from CMC 22 and monitor operations of the processing components of information handling system 10 to ensure that power consumption does not exceed the allocation. As another example, BMC 38 may receive temperatures sensed by temperature sensors 40 and apply the temperatures to ensure that thermal constraints are not exceeded.

A thermal manager 42 may execute as firmware, software, or other executable code on BMC 38 to manage thermal conditions within housing 12, such as the thermal state at particular processing components or ambient temperatures at discrete locations associated with housing 12. Thermal manager 42 may control the speed at which air movers 44 (e.g., cooling fans or cooling blowers) rotate to adjust a cooling airflow rate in housing 12 so that heat is removed at an appropriate temperature, so as to reduce overheating of a CPU 26 or prevent an excessive exhaust temperature as measured by an outlet temperature sensor 40. In the event that air movers 44 cannot provide sufficient cooling airflow to meet a thermal constraint, thermal manager 42 may reduce power consumption at one or more of the processing components to reduce the amount of thermal energy released into housing 12, such as by throttling the clock speed of one or more of CPUs 26. Thermal manager 42 may respond to extreme thermal conditions that place system integrity in jeopardy by shutting down information handling system 10, such as might happen if floor vent 20 fails to provide treated air due to a data center cooling system failure.

In order to more effectively manage thermal conditions associated with housing 12 in the event of a temporary or permanent failure of inlet temperature sensor 40, thermal manager 42 may apply conservation of energy to estimate thermal conditions at the location of inlet temperature sensor 40, and then use the estimated thermal conditions for more precise control of the overall thermal state of information handling system 10. For example, thermal manager 42 may perform one or more energy balances based upon available measures of power consumption, cooling fan speed, and sensed thermal conditions by one or more thermal sensors 40 other than inlet temperature sensor 40 in order to estimate the temperature at the location of inlet temperature sensor 40. The estimated inlet temperature may be applied to control of air movers 44 to maintain thermal constraints, including as a basis for open loop control of air movers 44 as a function of inlet temperature.

In some embodiments, thermal manager 42 may estimate thermal conditions at the location of inlet temperature sensor 40 by applying available component configuration information, such as a component inventory kept by BMC 38, and sensed, known, or estimated power consumption of the components. For example, BMC 38 may use actual power consumption of components or subassemblies if actual power consumption is available, known power consumption stored in the BMC inventory for known components, or estimated power consumption based upon the type of component and the component's own configuration. An example of estimated power consumption is a general estimate of power consumption stored in BMC 38 for unknown PCI cards 32 with the general estimate based upon the width of the PCI card, i.e., the number of links supported by the PCI card.

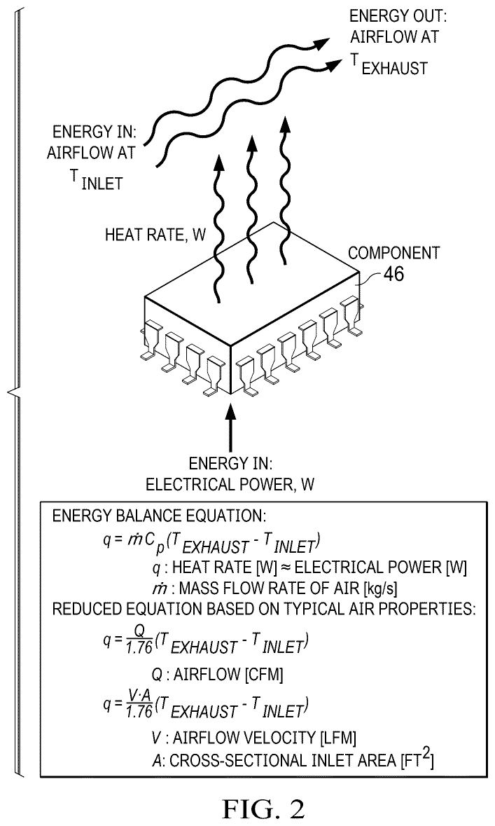

FIG. 2 illustrates a mathematical model for estimating thermal performance and setting thermal controls of component 46, in accordance with embodiments of the present disclosure. According to the law of conservation of energy, the total energy state of an information handling system is maintained as a balance of the energy into the system and the energy out of the system. The energy balance may be broken into a sum of a plurality of components 46 wherein each component 46 has a known or estimated power consumption that introduces thermal energy into the information handling system. The system energy balance becomes the energy into the system as reflected by an airflow inlet temperature, the thermal energy released by the sum of the components 46 that consume power in the system, and the energy out of the system as reflected by an airflow exhaust temperature. Energy removed from the system may relate to the mass flow rate of air flowing through the system and the coefficient for energy absorption of the cooling airflow. Simplified for the coefficient that typically applies to atmospheric air, the energy released by electrical power consumption may be equal to airflow in cubic feet per minute divided by a constant of 1.76 and multiplied by the difference between the exhaust temperature and inlet temperature. Alternatively, again simplified for the coefficient that typically applies to atmospheric air, the energy released by electrical power consumption may be equal to a linear airflow velocity in linear feet per minute (which may be calculated as a cubic airflow rate in cubic feet per minute multiplied by an area of an inlet of a component of interest (e.g., cross sectional area of inlet of a card)) divided by a constant of 1.76 and multiplied by the difference between the exhaust temperature and inlet temperature. Thermal manager 42 may apply one or both of these formulas to set a cooling fan speed to meet exhaust temperature constraints.

Applying conservation of energy and component power consumption to manage thermal conditions may allow more precise control of thermal conditions and discrete control within an information handling system housing even where measurements of actual thermal conditions by a temperature sensor 40, in particular inlet temperature sensor 40, are not available. Thus, using an estimate of a temperature for inlet temperature sensor 40 may enable thermal control, including open-loop thermal control, as a function of inlet temperature even when inlet temperature sensor 40 is unavailable.

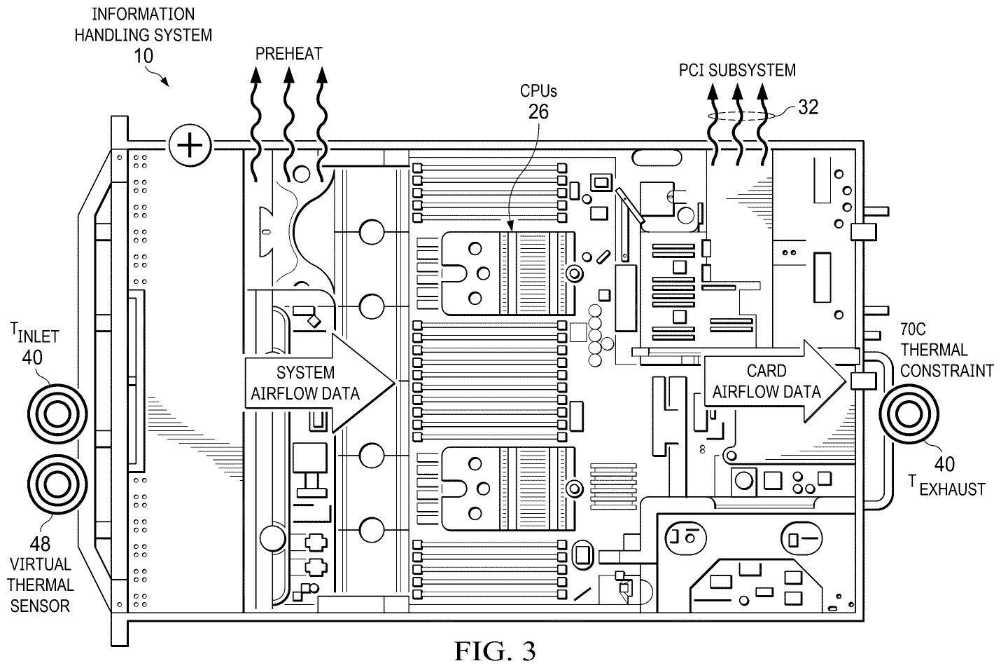

FIG. 3 illustrates a plan view of an example information handling system 10, in accordance with embodiments of the present disclosure. External air drawn into information handling system 10 may have an inlet temperature (T_{INLET}) measured by an inlet temperature sensor 40 and an airflow rate determined by the speed at which one or more cooling fans spin. As the cooling airflow passes through housing 12, it may absorb thermal energy resulting in a preheat of the airflow for downstream components. The cooling airflow may be forced from information handling system 10 at an exhaust with an exhaust temperature (T_{EXHAUST}) fixed at thermal constraint (e.g., 70° C.) as a requirement and/or measured by an exhaust temperature sensor 40. Thermal manager 42 may adapt cooling fan speed so that the cooling airflow temperature T_{EXHAUST} maintains a thermal constraint (e.g., 70° C.).

As shown in FIG. 3, a virtual thermal sensor 48 may be generated by thermal manager 42 at the location of inlet temperature sensor 40. Thermal manager 42 may apply configuration information stored in BMC 38 to determine the components that heat airflow within housing 12, may determine power consumed by the components, and obtain information from one or more other temperature sensors 40 (including outlet temperature sensor 40) to arrive at a virtual temperature measured by virtual thermal sensor 48. For example, thermal manager 42 may apply power consumed by CPUs 26 and static power consumption associated with other components to estimate inlet temperature T_{INLET} by conservation of energy. The virtual temperature for inlet temperature T_{INLET} may then be used for thermal management of information handling system 10, including without limitation, open-loop control of air movers 44 as a function of such estimated inlet temperature T_{INLET} in the absence of sensor information from inlet temperature sensor 40.

Generally, power consumption of components within information handling system 10 may be measured directly based upon power assigned by a power subsystem or estimated with a static value. Alternatively, power consumption may be derived from estimates using conservation of energy applied to known power consumption and thermal conditions in housing 12.

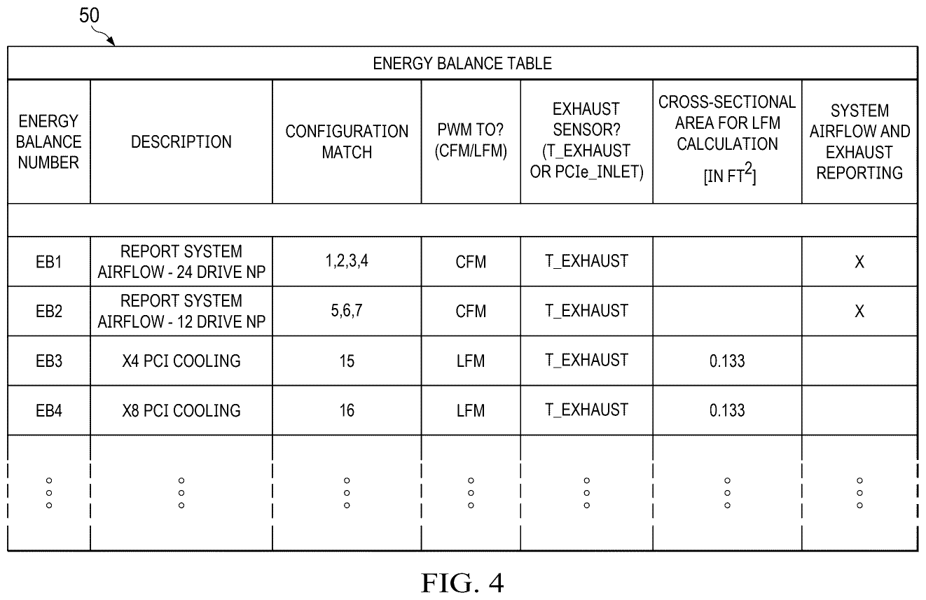

FIG. 4 illustrates a user interface for managing thermal conditions of a server information handling system with stored configuration settings of subsystems within the information handling system, in accordance with embodiments of the present disclosure. Energy balance table 50 may include energy balance parameters for components integral to information handing system 10 as well as estimated values for potential replacement components, such as non-specific PCI cards having a width of four or eight lanes. By including configuration match information that relates components to energy consumption, thermal manager 42 may be able to estimate a thermal condition based on detected components and energy balance information associated with such detected components as set forth in energy balance table 50.

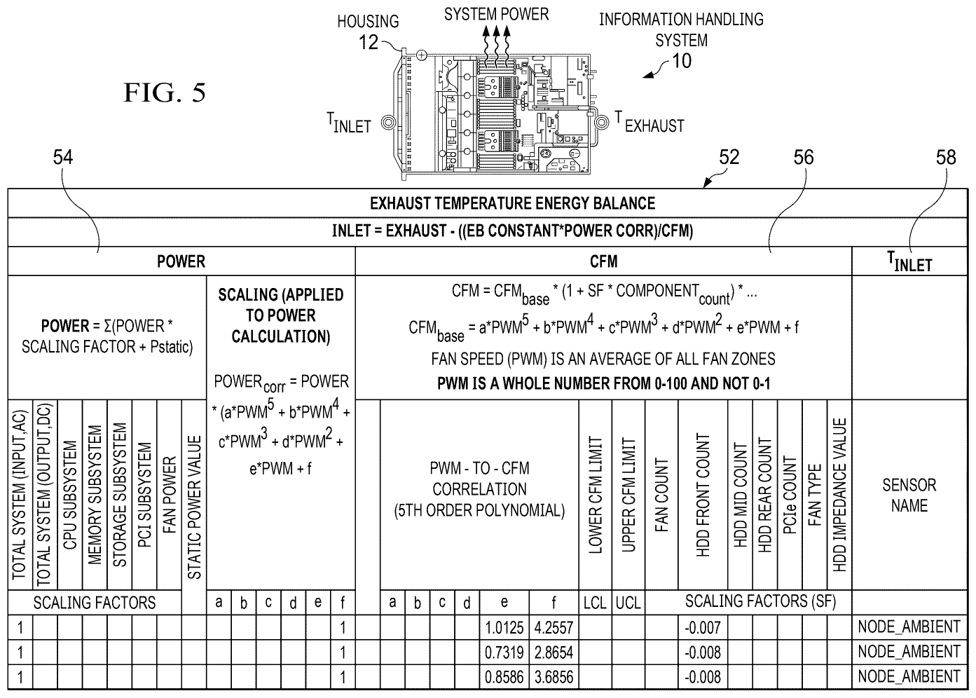

FIG. 5 illustrates a user interface for estimating system airflow and exhaust temperature based upon conservation of energy within an information handling system housing, in accordance with embodiments of the present disclosure. An exhaust temperature energy balance table 52 may apply power, cubic airflow, linear airflow velocity, and sensed temperature values to estimate thermal states and set control for desired cubic airflow, linear airflow velocity, and temperature parameters. A power window 54 may depict a power dissipation calculation performed for each subsystem having an energy balance number in energy balance table 50. A total system power dissipation may represent power use by all desired components, which in this example embodiment may include one or more cooling fans. Scaling factors may be set to adjust the relative power consumption in various configuration modes in response to dynamic power settings. A static power setting may also allow control to achieve a desired power setting at a component. A cubic airflow window 56 depicts a mass flow calculation in cubic feet per minute (CFM) and a linear airflow velocity window 58 depicts a linear airflow velocity in linear feet per minute (LFM) for determination of cubic airflow or linear airflow velocity to achieve the energy balance with the determined power settings for each component. The example embodiment depicted by FIG. 5 may estimate cubic airflow, linear airflow velocity, and inlet temperatures, with virtual temperature sensors. In particular, for a given pulse width modulation (PWM) value associated with cooling fans, inlet temperature energy balance table 52 may correlate such PWM value to an estimated cubic airflow (e.g., in CFM) and/or an estimated linear airflow velocity (e.g., in LFM) for configurations associated with the energy balance number.

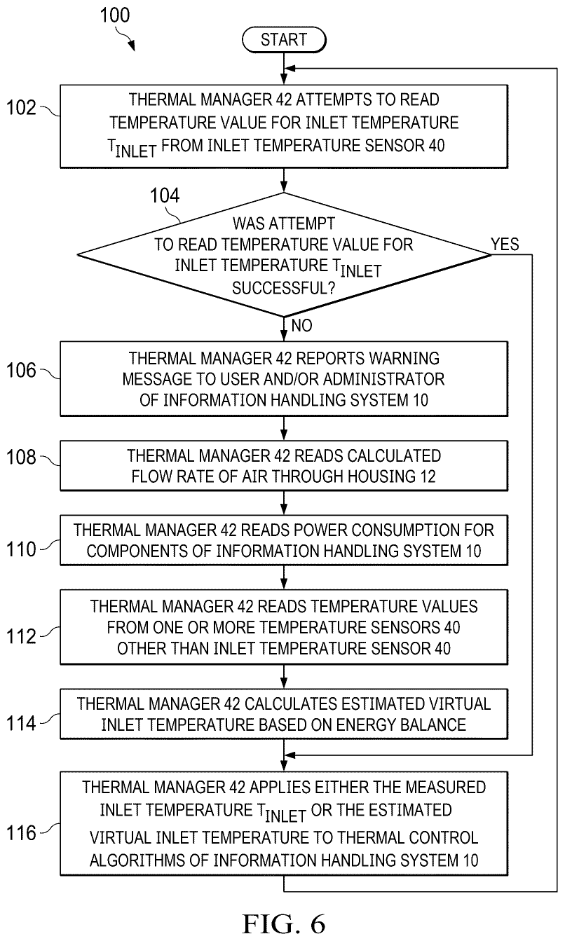

FIG. 6 illustrates a flow chart of an example method 100 for estimating an inlet temperature, in accordance with embodiments of the present disclosure. According to some embodiments, method 100 may begin at step 102. As noted above, teachings of the present disclosure may be implemented in a variety of configurations of information handling system 10. As such, the preferred initialization point for method 100 and the order of the steps comprising method 100 may depend on the implementation chosen.

At step 102, thermal manager 42 may attempt to read a temperature value for inlet temperature T_{INLET} from inlet temperature sensor 40. At step 104, thermal manager 42 may determine whether the attempt was successful. If the attempt to read the temperature value from inlet temperature sensor 40 was successful, method 100 may proceed to step 116. Otherwise method 100 may proceed to step 106.

At step 106, in response to the unavailability of temperature information from inlet temperature sensor 40, thermal manager 42 may report a warning message to a user and/or administrator of information handling system 10.

At step 108, thermal manager 42 may read a calculated flow rate (e.g., CFM flow rate) of air through housing 12.

At step 110, thermal manager 42 may read a power consumption for components of information handling system 10 (e.g., from a power sensor).

At step 112, thermal manager 42 may read temperature values from one or more temperature sensors 40 other than inlet temperature sensor 40. For example, in some embodiments, thermal manager 42 may read an exhaust temperature T_{EXHAUST} from outlet temperature sensor 40. In such embodiments, if the exhaust temperature T_{EXHAUST} from outlet temperature sensor 40 is unavailable, then thermal manager 42 may read temperature values from one or more other temperature sensors 40 within housing 12 and infer an exhaust temperature T_{EXHAUST} based on energy balance calculations. In other embodiments, thermal manager 42 may read temperature information from a plurality of temperature sensors 40 including outlet temperature sensor 40.

In some embodiments, thermal manager 42 may intelligently select which temperature sensor(s) 40 to use in the energy balance calculation. For example, thermal manager 42 may select one or more temperature sensor(s) 40 (e.g., in addition to outlet temperature sensor 40 when available or in lieu of outlet temperature sensor 40 when unavailable) which are significantly impacted by the ambient temperature to information handling system 10 but not as significantly impacted by heat generated by components internal to information handling system 10. Accordingly, for example, thermal manager 42 may prioritize use of passive temperature sensors on active devices or circuit boards over thermal sensors on active devices, as thermal sensors on active devices may experience self-heating. Further, thermal manager 42 may prioritize use of thermal sensors on active devices that are in low power or idle modes over thermal sensors on active devices that are in a normal operating mode such that the thermal sensors are more impacted by heat generation of the active devices than they are ambient temperature.

At step 114, thermal manager 42 may calculate an estimated virtual inlet temperature based on an energy balance with the flow rate from step 108, the power consumption from step 110, and the sensed temperature information from step 112.

At step 116, thermal manager 42 may apply either the measured inlet temperature T_{INLET} from step 102 or the estimated virtual inlet temperature from step 114 to thermal control algorithms (e.g., open-loop thermal control algorithms for air movers 44) of information handling system 10. After completion of step 116, method 100 may proceed again to step 102.

Although FIG. 6 discloses a particular number of steps to be taken with respect to method 100, method 100 may be executed with greater or fewer steps than those depicted in FIG. 6. In addition, although FIG. 6 discloses a certain order of steps to be taken with respect to method 100, the steps comprising method 100 may be completed in any suitable order.

Method 100 may be implemented using one or more information handling systems 10, components thereof, and/or any other system operable to implement method 100. In certain embodiments, method 100 may be implemented partially or fully in software and/or firmware embodied in computer-readable media.

Although not set forth in FIG. 6, in some embodiments, thermal manager 42 may also report a warning message to a user and/or administrator of information handling system 10 in the event that thermal manager 42 is unable to estimate a virtual inlet temperature and the actual inlet temperature T_{INLET} is unavailable.

In addition or alternatively, in some embodiments, thermal manager 42 may track an ambient temperature history of actual measurements from inlet temperature sensor 40, and, in the event of failure of inlet temperature sensor 40, thermal manager 42 may compare the estimated virtual inlet temperature to historical reading of the actual inlet temperature T_{INLET}, and correct the estimated virtual inlet temperature if the estimated virtual inlet temperature varies from the historical reading by the particular threshold.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S. C. § 112(f) unless the words “means for” or “step for” are explicitly used in the particular claim.

What is claimed is:

1. A system comprising:
a cooling subsystem comprising at least one air mover configured to generate a cooling airflow in the system;
a plurality of temperature sensors including an inlet temperature sensor for sensing an inlet temperature into the system of the cooling airflow and an outlet temperature sensor for sensing an exhaust temperature from the system of the cooling airflow; and
a thermal manager communicatively coupled to the cooling subsystem for control of the cooling subsystem and configured to:
control the cooling subsystem based at least in part on the inlet temperature when the inlet temperature sensor is available; and
in response to a failure of the inlet temperature sensor:
execute an energy balance calculation to estimate a virtual inlet temperature based on one or more temperature values from one or more temperature sensors of the plurality of temperature sensors other than the inlet temperature sensor; and
control the cooling subsystem based at least in part on the virtual inlet temperature when the inlet temperature sensor is unavailable.

2. The system of claim 1, wherein the one or more temperature values comprises the exhaust temperature sensed by the outlet temperature sensor.

3. The system of claim 1, wherein the one or more temperature values comprises one or more temperature values sensed by one or more temperature sensors other than the inlet temperature sensor and the outlet temperature sensor.

4. The system of claim 3, wherein the thermal manager is configured to:
infer an estimated exhaust temperature based on the one or more temperature sensors other than the inlet temperature sensor and the outlet temperature sensor; and
execute the energy balance calculation to estimate the virtual inlet temperature based on estimated exhaust temperature.

5. The system of claim 3, wherein the thermal manager is configured to select the one or more temperature sensors other than the inlet temperature sensor and the outlet temperature sensor based on a determination of which temperature sensors within the system are impacted more significantly by inlet temperature than by heating from devices internal to the system.

6. The system of claim 1, wherein the thermal manager is further configured to communicate a warning in response to a failure of the inlet temperature sensor.

7. The system of claim 1, wherein the thermal manager is further configured to execute the energy balance calculation further based on a flow rate of the cooling airflow and power consumption of components of the system.

8. The system of claim 1, wherein the thermal manager is further configured to:
compare the virtual inlet temperature to historical readings of the inlet temperature; and
apply a correction to the virtual inlet temperature if the virtual inlet temperature varies from the historical readings by a particular threshold.

9. A method comprising:
controlling a cooling subsystem, the cooling subsystem comprising at least one air mover configured to generate a cooling airflow in a system, based at least in part on an inlet temperature to the system when an inlet temperature sensor for sensing the inlet temperature is available; and
in response to a failure of the inlet temperature sensor:
executing an energy balance calculation to estimate a virtual inlet temperature based on one or more temperature values from one or more temperature sensors of a plurality of temperature sensors of the system other than the inlet temperature sensor; and
controlling the cooling subsystem based at least in part on the virtual inlet temperature when the inlet temperature sensor is unavailable.

10. The method of claim 9, wherein the one or more temperature values comprises an exhaust temperature of the system sensed by an outlet temperature sensor.

11. The method of claim 9, wherein the one or more temperature values comprises one or more temperature values sensed by one or more temperature sensors other than the inlet temperature sensor and an outlet temperature sensor for sensing exhaust temperature of the system.

12. The method of claim 11, further comprising:
inferring an estimated exhaust temperature based on the one or more temperature sensors other than the inlet temperature sensor and the outlet temperature sensor; and
executing the energy balance calculation to estimate the virtual inlet temperature based on estimated exhaust temperature.

13. The method of claim 11, further comprising selecting the one or more temperature sensors other than the inlet temperature sensor and the outlet temperature sensor based on a determination of which temperature sensors within the system are impacted more significantly by inlet temperature than by heating from devices internal to the system.

14. The method of claim 9, further comprising communicating a warning in response to a failure of the inlet temperature sensor.

15. The method of claim 9, further comprising executing the energy balance calculation further based on a flow rate of the cooling airflow and power consumption of components of the system.

16. The method of claim 9, further comprising:
comparing the virtual inlet temperature to historical readings of the inlet temperature; and
applying a correction to the virtual inlet temperature if the virtual inlet temperature varies from the historical readings by a particular threshold.

17. An article of manufacture comprising:
a non-transitory computer-readable medium; and
computer-executable instructions carried on the computer-readable medium, the instructions readable by a processor, the instructions, when read and executed, for causing the processor to:
control a cooling subsystem, the cooling subsystem comprising at least one air mover configured to generate a cooling airflow in a system, based at least in part on an inlet temperature to the system when an inlet temperature sensor for sensing the inlet temperature is available; and
in response to a failure of the inlet temperature sensor:
execute an energy balance calculation to estimate a virtual inlet temperature based on one or more temperature values from one or more temperature sensors of a plurality of temperature sensors of the system other than the inlet temperature sensor; and
control the cooling subsystem based at least in part on the virtual inlet temperature when the inlet temperature sensor is unavailable.

18. The article of claim 17, wherein the one or more temperature values comprises an exhaust temperature of the system sensed by an outlet temperature sensor.

19. The article of claim 17, wherein the one or more temperature values comprises one or more temperature values sensed by one or more temperature sensors other than the inlet temperature sensor and an outlet temperature sensor for sensing exhaust temperature of the system.

20. The article of claim 19, the instructions for further causing the processor to:
infer an estimated exhaust temperature based on the one or more temperature sensors other than the inlet temperature sensor and the outlet temperature sensor; and
execute the energy balance calculation to estimate the virtual inlet temperature based on estimated exhaust temperature.

21. The article of claim 19, the instructions for further causing the processor to select the one or more temperature sensors other than the inlet temperature sensor and the outlet temperature sensor based on a determination of which temperature sensors within the system are impacted more significantly by inlet temperature than by heating from devices internal to the system.

22. The article of claim 17, the instructions for further causing the processor to communicate a warning in response to a failure of the inlet temperature sensor.

23. The article of claim 17, the instructions for further causing the processor to execute the energy balance calculation further based on a flow rate of the cooling airflow and power consumption of components of the system.

24. The article of claim 17, the instructions for further causing the processor to:
compare the virtual inlet temperature to historical readings of the inlet temperature; and
apply a correction to the virtual inlet temperature if the virtual inlet temperature varies from the historical readings by a particular threshold.
